(19) United States
(12) Patent Application Publication
(10) Pub. No.: US 2024/0330028 A1
(43) Pub. Date: Oct. 3, 2024

(54) VIRTUAL SENSOR SYSTEM FOR DIGITAL TWIN APPLICATION

(71) Applicant: ELECTRONICS AND TELECOMMUNICATIONS RESEARCH INSTITUTE, Daejeon (KR)

(72) Inventors: Won Kyu CHOI, Daejeon (KR); Se Han KIM, Daejeon (KR); Hyeon PARK, Daejeon (KR); Jae Young JUNG, Daejeon (KR); Sung Soo KWON, Daejeon (KR); Su Jin PARK, Daejeon (KR); Ji Hoon BAE, Daejeon (KR); Yu Jin HAN, Daejeon (KR)

(21) Appl. No.: 18/619,430

(22) Filed: Mar. 28, 2024

(30) Foreign Application Priority Data
Mar. 29, 2023 (KR) 10-2023-0041438

(51) Int. Cl. G06F 9/455

(52) U.S. Cl. CPC G06F 9/455

(57) ABSTRACT

Provided is a virtual sensor system for a digital twin application. The virtual sensor system includes an edge gateway configured to collect data collected from physical sensors in the real world, apply the collected data to a virtual sensor model, and operate virtual sensors for configuring a digital twin world, and a virtual sensor framework configured to train the virtual sensor model using data, which is measured by the physical sensors, from the edge gateway and distribute the virtual sensor model to the edge gateway.

### CROSS-REFERENCE TO RELATED APPLICATION

This application claims priority to and the benefit of Korean Patent Application No. 10-2023-0041438, filed on Mar. 29, 2023, the disclosure of which is incorporated herein by reference in its entirety.

### BACKGROUND

### 1. Field of the Invention

The present invention relates to a virtual sensor system for a digital twin application.

### 2. Description of Related Art

Virtual sensors may be implemented based on a mathematical theory or model (first-principle), implemented based on pure data (black-box), or implemented by combining a model and data (gray-box). In addition to the above concepts, virtual sensors may be implemented based on a digital twin. In addition to digital twin applications, virtual sensors may be useful even in environments where it is difficult to install and operate sensors for economic reasons, or where it is difficult to physically install and maintain sensors. Virtual sensors may be used for purposes such as backup, replacement, observation, fault detection & diagnosis, etc.

Further, levels of implementing virtual sensors may be divided into four levels. Level 1 is a level of implementing a single physical sensor as the same virtual sensor, and level 2 is a level of implementing a homogeneous combined sensor based on several homogeneous sensors and data. This is used as a way to implement highly reliable virtual sensors. Level 3 is a level of implementing a virtual sensor by statically combining different heterogeneous sensors and data, and Level 4 is a level of implementing a virtual sensor by dynamically combining different heterogeneous sensors and data.

In order to implement highly reliable virtual sensors, precise modeling of an environment is required and a plurality of pieces of high-fidelity data containing accurate environmental information are required. In order to collect a plurality of pieces of high-fidelity data, highly reliable Internet of things (IoT) sensors are required.

Sensors for monitoring the safety of bridges may include acceleration sensors, expansion joint sensors, tilt sensors, etc. These sensors have high costs, and due to the poor external environment, a large budget is required for sensor installation and maintenance. In order to periodically monitor the safety of bridges, various sensors should be installed and operated on the bridges, but the safety of bridges based on IoT sensors cannot be managed due to economic issues.

### SUMMARY OF THE INVENTION

The present invention is directed to providing a virtual sensor system for a digital twin application that can predict current and future values at a specific location using a plurality of pieces of data collected from a bridge.

According to an aspect of the present invention, there is provided a virtual sensor system for a digital twin application, which includes an edge gateway configured to collect data collected from physical sensors in the real world, apply the collected data to a virtual sensor model, and operate virtual sensors for configuring a digital twin world, and a virtual sensor framework configured to train the virtual sensor model using data, which is measured by the physical sensors, from the edge gateway and distribute the virtual sensor model to the edge gateway.

The virtual sensor model may predict time series data on the basis of correlation characteristics of the data collected from the physical sensors and the data collected from the physical sensors at a current moment in order to construct a digital twin world in the field of bridges.

The virtual sensor model may learn based on the data collected from the physical sensors that are correlated with each other and predicts time series data in an area where no physical sensor is installed.

The edge gateway may include a database configured to collect the data from the physical sensors, a data preprocessing module configured to preprocess the data stored in the database, a virtual sensor database configured to store the virtual sensor model, and a virtual sensor operation module configured to operate the virtual sensors through the virtual sensor model using the data preprocessed in the data preprocessing module.

The edge gateway may further include an abnormal signal detection module configured to, when it is determined that the characteristics of the data preprocessed in the data preprocessing module have changed, request update of the virtual sensor model from the virtual sensor framework according to a distribution of the changed data.

When the data preprocessed in the data preprocessing module is an abnormal signal, the abnormal signal detection module may transmit an alarm to an administrator so that the administrator is able to check whether there is an abnormality in the physical sensors.

When an error between time series data measured by the physical sensors and time series data restored by a deep learning model for detecting an abnormal signal is greater than a preset threshold, the abnormal signal detection module may determine that the data is an abnormal signal, and when the error is smaller than the threshold, the abnormal signal detection module may determine that the data is a normal signal.

The virtual sensor framework may include a database configured to store preprocessed data from the edge gateway, a virtual sensor learning model module configured to train the virtual sensor model with the data stored in the database and generate the virtual sensors, a signal error analysis module configured to compare the data stored in the database with data of the virtual sensors input from the virtual sensor learning model module and correct errors of the virtual sensors, and a data and error monitoring visualization engine configured to monitor the data stored in the database and the errors received from the signal error analysis module, determine whether the virtual sensor model needs to be updated, and request data collection for learning from the edge gateway according to a result of the determination.

The virtual sensor learning model module may include an encoder configured to receive time series data of the physical sensors as an input and a decoder configured to receive the time series data of the physical sensors as an input, and the virtual sensor learning model module may set the time series data of the physical sensors as an input of the encoder, may set the time series data of the physical sensors as an input of the decoder, may set a result of applying teacher forcing to an input sequence of the decoder as a target sequence of the decoder, and may perform training of the virtual sensor model by inputting a last internal state of the encoder as an initial state of the decoder.

The virtual sensor model may include a recurrent neural network (RNN)-based encoder and an RNN-based decoder, the encoder and the decoder may be composed of a cell RNN with a stacked structure, and the cell RNN may be implemented with at least one of a SimpleRNN, a long short-term memory (LSTM), and a gated recurrent unit (GRU).

The virtual sensor model may store a final hidden state of the encoder in a state input representation layer (state), then inputs the final hidden state as the initial state of the decoder, generates a target sequence by shifting an input sequence of the decoder by one time step, and then sets an output signal that passes through a time-distributed fully connected layer as a target signal to perform learning, and the time-distributed fully connected layer may perform learning so that the decoder is able to know what a next target signal is at each time step.

The signal error analysis module may obtain an absolute value of an error between the data of the virtual sensors and data of the physical sensors, obtain an absolute error average during a set period, and then monitor the errors of the virtual sensors by performing an exponential moving average on the absolute error average.

According to another aspect of the present invention, there is provided a virtual sensor system for a digital twin application, which includes a database configured to collect data from physical sensors, a data preprocessing module configured to preprocess the data stored in the database, a virtual sensor database configured to store a virtual sensor model, an abnormal signal detection module configured to, when it is determined that the characteristics of the data preprocessed in the data preprocessing module have changed, request update of the virtual sensor model from a virtual sensor framework according to a distribution of the changed data, and a virtual sensor operation module configured to operate virtual sensors through the virtual sensor model using the data preprocessed in the data preprocessing module.

When an error between time series data measured by the physical sensors and time series data restored by a deep learning model for detecting an abnormal signal is greater than a preset threshold, the abnormal signal detection module may determine that the data is an abnormal signal, and when the error is smaller than the threshold, the abnormal signal detection module may determine that the data is a normal signal.

According to still another aspect of the present invention, there is provided a virtual sensor system for a digital twin application, which includes a database configured to store preprocessed data from an edge gateway, a virtual sensor learning model module configured to train a virtual sensor model with the data stored in the database and generate virtual sensors, and a signal error analysis module configured to compare the data stored in the database with data of the virtual sensors input from the virtual sensor learning model module and correct errors of the virtual sensors.

The virtual sensor system may further include a data and error monitoring visualization engine configured to monitor the data stored in the database and the errors received from the signal error analysis module, determine whether the virtual sensor model needs to be updated, and request data collection for learning from the edge gateway according to a result of the determination.

The virtual sensor learning model module may include an encoder configured to receive time series data of the physical sensors as an input and a decoder configured to receive the time series data of the physical sensors as an input, and the virtual sensor learning model module may set the time series data of the physical sensors as an input of the encoder, set the time series data of the physical sensors as an input of the decoder, set a result of applying teacher forcing to an input sequence of the decoder as a target sequence of the decoder, and perform training of the virtual sensor model by inputting a last internal state of the encoder as an initial state of the decoder.

The virtual sensor model may include an RNN-based encoder and an RNN-based decoder, the encoder and the decoder may be composed of a cell RNN with a stacked structure, the virtual sensor model may store a final hidden state of the encoder in a state input representation layer (state), then input the final hidden state as the initial state of the decoder, generate a target sequence by shifting an input sequence of the decoder by one time step, and then set an output signal that passes through a time-distributed fully connected layer as a target signal to perform learning, and the time-distributed fully connected layer may perform learning so that the decoder is able to know what a next target signal is at each time step.

The signal error analysis module may obtain an absolute value of an error between the data of the virtual sensors and data of physical sensors, obtain an absolute error average during a set period, and then monitor errors of the virtual sensors by performing an exponential moving average on the absolute error average.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a set of conceptual diagrams of bridge application digital twin technology according to an embodiment of the present invention;

FIG. 2 is a diagram showing an example of installation of physical sensors in a bridge environment according to an embodiment of the present invention;

FIG. 3 is a diagram showing an example of installation and operation of virtual sensors in a bridge environment according to an embodiment of the present invention;

FIG. 4 is a diagram showing another example of installation and operation of virtual sensors in a bridge environment according to an embodiment of the present invention;

FIG. 5 is a configuration diagram of a system for generating, managing, and operating virtual sensors according to an embodiment of the present invention;

FIG. 6 is a diagram showing an example of predicting a target signal using a recurrent neural network in a bridge environment according to an embodiment of the present invention;

FIG. 7 is a detailed structural diagram of a virtual sensor learning model of FIG. 6;

FIG. 8 is a conceptual diagram of signal generation of an inference model of a virtual sensor output layer (decoder) according to an embodiment of the present invention;

FIG. 9 is a configuration diagram of an error analysis model for a signal generated by a virtual sensor according to an embodiment of the present invention;

FIG. 10 is a diagram showing a deep learning model for detecting an abnormal signal in sensor data according to an embodiment of the present invention; and

FIG. 11 is a diagram showing an example of detecting an abnormal signal in sensor data according to an embodiment of the present invention.

### DETAILED DESCRIPTION OF EXEMPLARY EMBODIMENTS

Hereinafter, examples of a virtual sensor system for a digital twin application according to embodiments of the present invention will be described. In this process, thicknesses of lines, sizes of components, and the like shown in the accompanying drawings may be exaggerated for clarity and convenience of description. Further, some terms which will be described below are defined in consideration of functions in the present invention and meanings may vary depending on, for example, a user or operator's intentions or customs. Therefore, the meanings of these terms should be interpreted based on the scope throughout this specification.

Hereinafter, embodiments of the present invention will be described in detail with reference to the accompanying drawings so that the embodiments can be easily performed by those skilled in the art. However, embodiments of the present invention may be implemented in several different forms, and are not limited to embodiments described herein. In addition, parts irrelevant to description are omitted in the drawings in order to clearly explain embodiments of the present invention. Similar parts are denoted by similar reference numerals throughout this specification.

Throughout this specification, when a certain part “includes” a certain component, it means that another component may be further included rather than other components being excluded unless otherwise stated.

Implementations described herein may be implemented, for example, as a method, a process, a device, a software program, a data stream, or a signal. Although discussed only in the context of a single form of implementation (e.g., only as a method), implementations of the features discussed may also be implemented in other forms (e.g., devices or programs). The device may be implemented with appropriate hardware, software, firmware, etc. The method may be implemented in a device such as a processor, which is generally a processing device including a computer, microprocessor, integrated circuit, or programmable logic device.

In an embodiment of the present invention, a virtual sensor based on a deep learning model that can predict current and future values at a specific location using a plurality of pieces of data collected from a bridge will be described as an example.

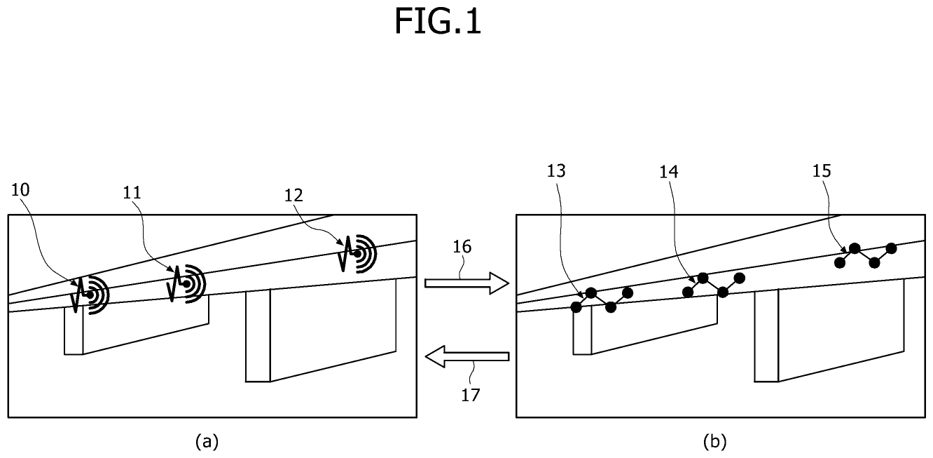

FIG. 1 is a set of conceptual diagrams of bridge application digital twin technology according to an embodiment of the present invention.

FIG. 1A shows the real world around a bridge. Various physical sensors 10, 11, and 12 for measuring a bridge environment and momentum are installed in the real world of FIG. 1A.

FIG. 1B shows a digital twin world of the bridge. In the digital twin world of FIG. 1B, an actual bridge environment (FIG. 1A) is almost identically replicated in a digital virtual environment by modeling and simulating the real world (FIG. 1A). Further, in order to increase the reliability of the digital twin world of FIG. 1B, data measured by the physical sensors of the real world (FIG. 1A) is transmitted to the digital twin world (FIG. 1B) through a predetermined communication protocol 16.

The actual measurement data transmitted to the digital twin world is reflected in locations 13, 14, and 15 where the physical sensors are installed, and is used to tune or correct a digital twin model. Measurement time series data of the physical sensors 10, 11, and 12 installed in the real world (FIG. 1A) may be continuously reflected in the corresponding locations 13, 14, and 15 in the digital twin world (FIG. 1B), and thus a highly reliable digital twin world may be generated.

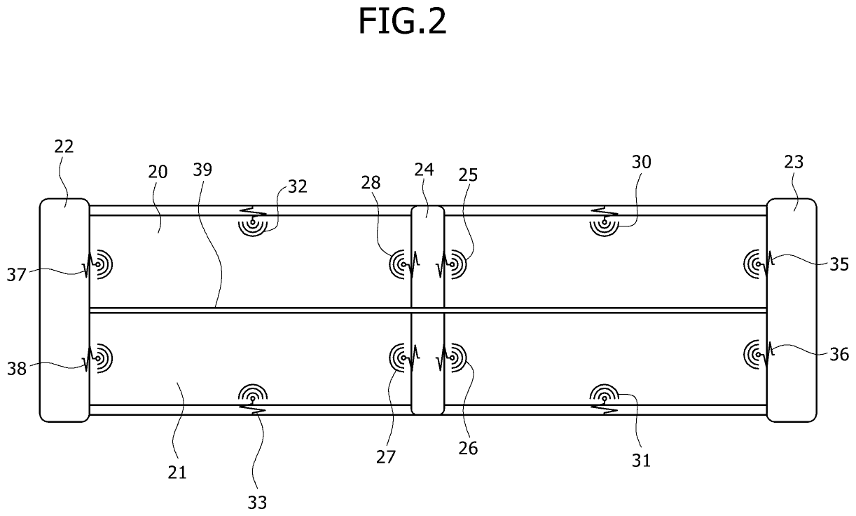

FIG. 2 is a diagram showing an example of installation of physical sensors in a bridge environment according to an embodiment of the present invention.

FIG. 2 is a top view of a typical small two-way two-lane bridge.

The bridge of FIG. 2 consists of two-way two-lanes 20 and 21 on which vehicles can come and go relative to a center line 39. The bridge consists of two abutments 22 and 23 connected to the road (land) and a pier 24 that supports two bridge decks at the center of the bridge.

In order to monitor the safety of the bridge of FIG. 2, various physical sensors should be installed. That is, expansion joint sensors (may also be strain gauge sensors) 35, 36, 37, and 38 for measuring length deformation of the bridge according to an external temperature may be installed on junctions between the abutments 22 and 23 and the bridge decks for each of the lanes 20 and 21. Tilt sensors 25, 26, 27, and 28 for measuring the tilt of the bridge may be installed on junctions between the pier 24 in the center of the bridge and the bridge decks. Further, in order to measure the vibration movement characteristics of the bridge according to traffic volume, acceleration sensors 30, 31, 32, and 33 may be installed on central portions of the bridge decks. When the physical sensors are installed as shown in FIG. 2, the movement characteristics of the bridge may be accurately measured, which is more advantageous for providing precise data in a digital twin world.

The bridge of FIG. 2 has a structure that is left and right symmetrical with respect to the pier 24 that supports the two bridge decks. Therefore, it is possible to analyze and define the data correlation characteristics of four expansion joint sensors 35, 36, 37, and 38, four tilt sensors 25, 26, 27, and 28, and four acceleration sensors 30, 31, 32, and 33 on the basis of the collected data. Time series data at a specific location, that is, a physical quantity, may be predicted based on the correlation characteristics and data collected at a current moment.

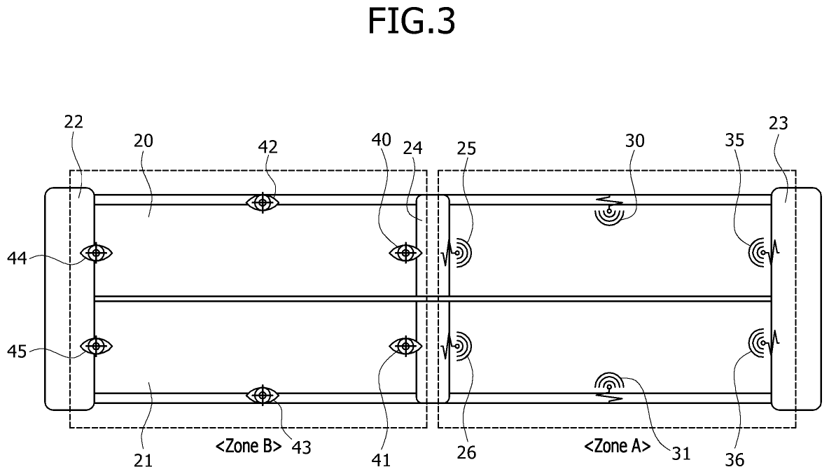

FIG. 3 is a diagram showing an example of installation and operation of virtual sensors in a bridge environment according to an embodiment of the present invention.

A bridge of FIG. 3 has a structure that is left and right symmetrical with respect to the pier 24 that supports the two bridge decks. Using this symmetry, the sensors in Zone B may be replaced with virtual sensors and operated on the basis of actual measurement data collected in Zones A and B of FIG. 3. That is, with regard to expansion joint sensors 35, 36, 44, and 45, an expansion joint virtual sensor model that is trained based on expansion joint data collected in the past may predict data of the expansion joint sensors 44 and 45 in Zone B on the basis of data of the expansion joint sensors 35 and 36 in Zone A that is being collected at a current moment (present moment). That is, the expansion joint sensors 44 and 45 installed in Zone B may be replaced with virtual sensors.

Further, with regard to tilt sensors 25, 26, 40, and 41, a tilt virtual sensor model that is trained based on tilt data collected in the past may predict data of the tilt sensors 40 and 41 in Zone B on the basis of data of the tilt sensors 25 and 26 in Zone A that is being collected at a current moment. That is, the tilt sensors 40 and 41 installed in Zone B may be replaced with virtual sensors. Then, with regard to acceleration sensors 30, 31, 42, and 43, an acceleration virtual sensor model that is trained based on acceleration data collected in the past may predict data of the acceleration sensors 42 and 43 in Zone B on the basis of data of the acceleration sensors 30 and 31 in Zone A that is being collected at a current moment. That is, the acceleration sensors 42 and 43 installed in Zone B may be replaced with virtual sensors.

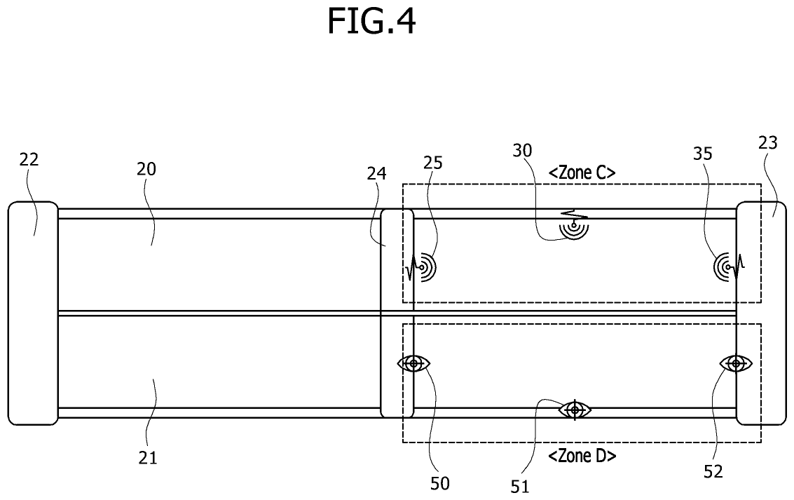

FIG. 4 is a diagram showing another example of installation and operation of virtual sensors in a bridge environment according to an embodiment of the present invention.

A bridge of FIG. 4 is a small bridge composed of two-way two-lanes 20 and 21. Regardless of in which of the two lanes 20 and 21 a vehicle travels, the momentum of the bridge moving in a vertical direction is likely to have a certain correlation in the two lanes 20 and 21. That is, when the vehicle moves in the upper lane 20 of FIG. 4, the movement of the vehicle may have a certain impact on the lower lane 21, and likewise when the vehicle moves in the lower lane 21 of FIG. 4, the movement of the vehicle may have a certain impact on the upper lane 20. That is, using the symmetry of the bridge, sensors in Zone D may be replaced with virtual sensors on the basis of actual measurement data collected in Zones C and D of FIG. 4.

With regard to expansion joint sensors 35 and 52, an expansion joint virtual sensor model that is trained based on expansion joint data collected in the past may predict data of the expansion joint sensor 52 in Zone D on the basis of data of an expansion joint sensor 53 in Zone C that is being collected at a current moment. That is, the expansion joint sensor 52 installed in Zone D may be replaced with a virtual sensor. Further, with regard to tilt sensors 25 and 50, a tilt virtual sensor model that is trained based on tilt data collected in the past may predict data of the tilt sensor 50 in Zone D on the basis of data of the tilt sensor 25 in Zone C that is being collected at a current moment. That is, the tilt sensor 50 installed in Zone D may be replaced with a virtual sensor. Then, with regard to acceleration sensors 30 and 51, an acceleration virtual sensor model that is trained based on acceleration data collected in the past may predict data of the acceleration sensor 51 in Zone D on the basis of data of the acceleration sensor 30 in Zone C that is being collected at a current moment. That is, the acceleration sensor 51 installed in Zone D may be replaced with an acceleration sensor.

In this way, the virtual sensors learn based on the data of the physical sensors that are correlated with each other to predict time series data in an area where no physical sensor is installed.

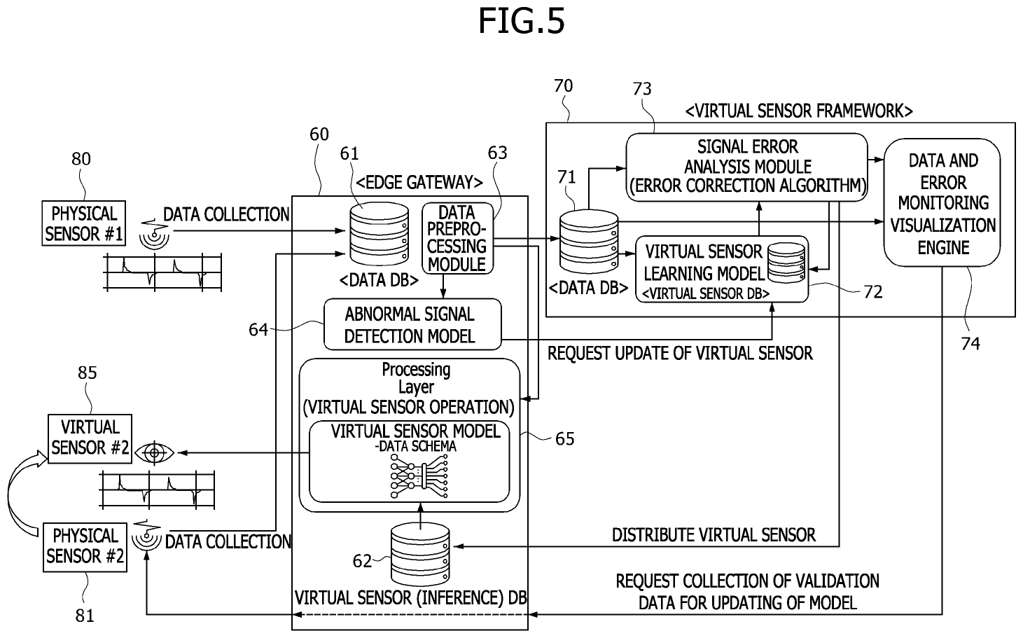

FIG. 5 is a configuration diagram of a system for generating, managing, and operating virtual sensors according to an embodiment of the present invention.

Referring to FIG. 5, the system for generating, managing, and operating virtual sensors includes an edge gateway 60 that collects and manages data in the real world where physical sensors are installed and operates virtual sensors, and a virtual sensor framework 70 for learning and verification of the virtual sensors.

The edge gateway 60 collects the data collected from the physical sensors in the real world, and applies the collected data to a virtual sensor model to operate the virtual sensors for generating a digital twin world.

Further, the virtual sensor framework 70 trains the virtual sensor model using the data, which is measured by the physical sensors, from the edge gateway 60 and distributes the virtual sensor model to the edge gateway 60.

Generally, a plurality of physical sensors 80 and 81 are installed at meaningful and appropriate locations in the real world.

In order to implement data-based virtual sensors, the edge gateway 60 collects raw data from the physical sensors 80 and 81 and stores the collected raw data in a database 61, and a data preprocessing module 63 preprocesses the collected raw data in the form of data appropriate for implementing virtual sensors.

An abnormal signal detection model 64 determines whether the data preprocessed in the data preprocessing module 63 is an abnormal signal. When it is determined that the data is an abnormal signal, the abnormal signal detection model 64 may transmit an alarm to an administrator so that the administrator can check whether there is an abnormality in the sensor installed in the real world. Alternatively, when it is determined that the data is not an abnormal signal and that the overall characteristics of the data have changed, the abnormal signal detection model 64 may request an update from a virtual sensor learning model module 72 so that the virtual sensor model can be updated with a virtual sensor appropriate for the data distribution changed by the virtual sensor framework 70. When there is no abnormality in a result of the data preprocessing module 63, the preprocessed data is used for operating the virtual sensor in the virtual sensor operation module 65.

The virtual sensor operated in the virtual sensor operation module 65 of the edge gateway 60 has the effect of a virtual sensor 85 operated in the real world.

Further, the edge gateway 60 has a virtual sensor database 62 that can store and manage a virtual sensor inference model verified and distributed in the virtual sensor framework 70.

The virtual sensor framework 70 for learning and verification of the virtual sensors includes a database 71 for storing the preprocessed data received from the data preprocessing module 63 of the edge gateway 60, a virtual sensor learning model module 72 for generating virtual sensors, a signal error analysis module 73 for correcting errors in a learned virtual sensor, and a data and error monitoring visualization engine 74 that can monitor data errors.

The preprocessed data that is stored in the database 71 for learning of the virtual sensor is transmitted to the virtual sensor learning model module 72.

The virtual sensor model learned in the virtual sensor learning model module 72 is transmitted to the signal error analysis module 73 having an error correction algorithm.

The signal error analysis module 73 compares the data of the physical sensor received from the database 71 with a predicted data value of the virtual sensor, and when the error exceeds an allowable range, the virtual sensor model is tuned using the error correction algorithm so that the error remains within the allowable range.

Finally, the tuned virtual sensor model is stored in the virtual sensor learning model module 72 having the virtual sensor database, and at the same time, is distributed to the virtual sensor database 62 included in the edge gateway 60.

The data and error monitoring visualization engine 74 may monitor raw data and preprocessed data received from the database 71 and monitor signal errors received from the signal error analysis module 73, and when the virtual sensor model needs to be updated, the data and error monitoring visualization engine 74 may request collection of additional learning data required for update from the edge gateway 60.

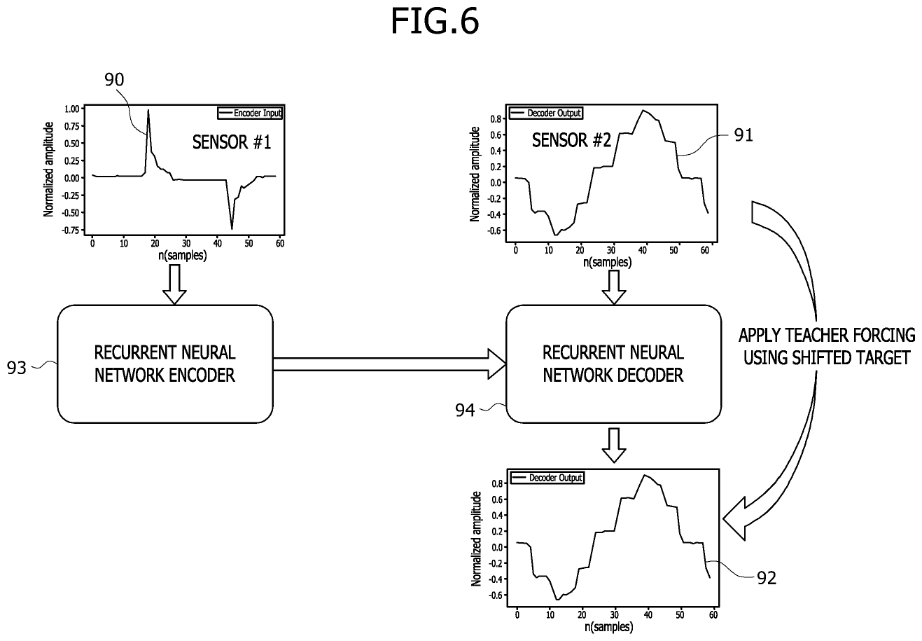

FIG. 6 is a diagram showing an example of predicting a target signal using a recurrent neural network (RNN) in a bridge environment according to an embodiment of the present invention.

In the real world, two physical sensors 90 and 91 that are correlated with each other are installed.

FIG. 6 is a configuration diagram of an RNN-based encoder-decoder model that generates an output of the physical sensor #2 91 using an RNN encoder 93 that receives the time series data of the physical sensor #1 90 as an input and an RNN decoder 94 that receives the time series data of the physical sensor #2 91 as an input. That is, after the time series data of the physical sensor #1 90 is set as an input of the encoder 93 and the time series data of the physical sensor #2 91 is set as an input of the decoder 94, learning is performed by setting a result that is obtained by applying teacher forcing to the input sequence 91 of the decoder 94 as the target sequence 92 of the decoder 94. Further, learning is performed by inputting a final internal state of the encoder 93 as an initial state of the decoder 94.

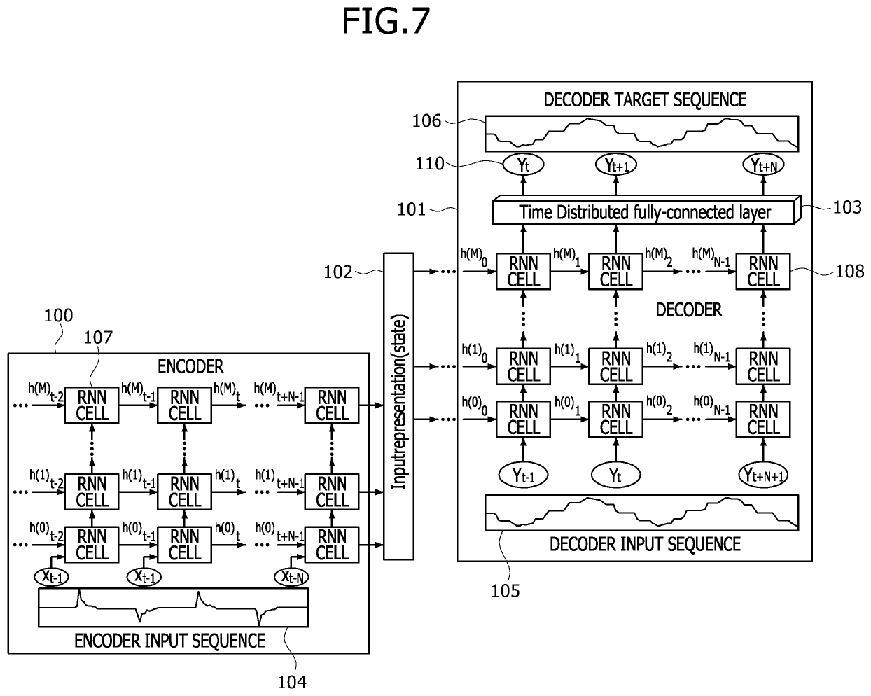

FIG. 7 is a detailed structural diagram of the virtual sensor learning model of FIG. 6.

The virtual sensor of the present embodiment is a model consisting of an RNN-based encoder 100 and an RNN-based decoder 101.

The encoder is composed of a cell RNN 107 with a stacked structure, and the decoder is also composed of a cell RNN 108 with a stacked structure.

The cell RNNs 107 and 108 may be implemented with a SimpleRNN, a long short-term memory (LSTM), and a gated recurrent unit (GRU).

When an RNN-based encoder-decoder model is learned, learning is performed by inputting a final hidden state of each layer of the encoder 100 as an initial state of the decoder 101. The final hidden state of the encoder 100 is stored in a state input representation layer (state) 102 and then is input to the decoder 101. After an input sequence 109 of the decoder 101 is shifted to the right by one time step to generate a target sequence, learning is performed by setting an output signal that has passed through a time-distributed fully connected layer 103 as a target signal 110.

The time-distributed fully connected layer 103 performs learning so that the decoder 101 can know what a next target signal is at each time step. When learning is completed, a target sequence 106 of the decoder 101 may be predicted using an input sequence 104 of the encoder 100 and an input sequence 105 of the decoder 101.

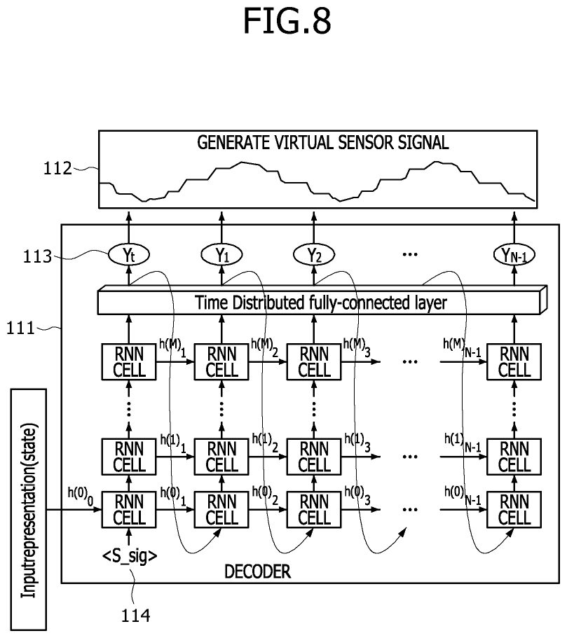

FIG. 8 is a conceptual diagram of signal generation of an inference model of a virtual sensor output layer (decoder) according to an embodiment of the present invention.

Referring to FIG. 8, when a virtual sensor signal 112 is generated, a signal 113 output at a previous time step is used as an input to an RNN cell of a next time step, and the same operation as above is repeatedly performed by a data length of a time series sequence of a physical sensor input to an encoder. In this case, a start S_sig 114 of a sequence input to a decoder 111 is a start signal for generating a virtual sensor signal, and uses a first input value of the time series sequence of the physical sensor input to the encoder. Further, an inference model may be operated by setting a different type of starting signal value.

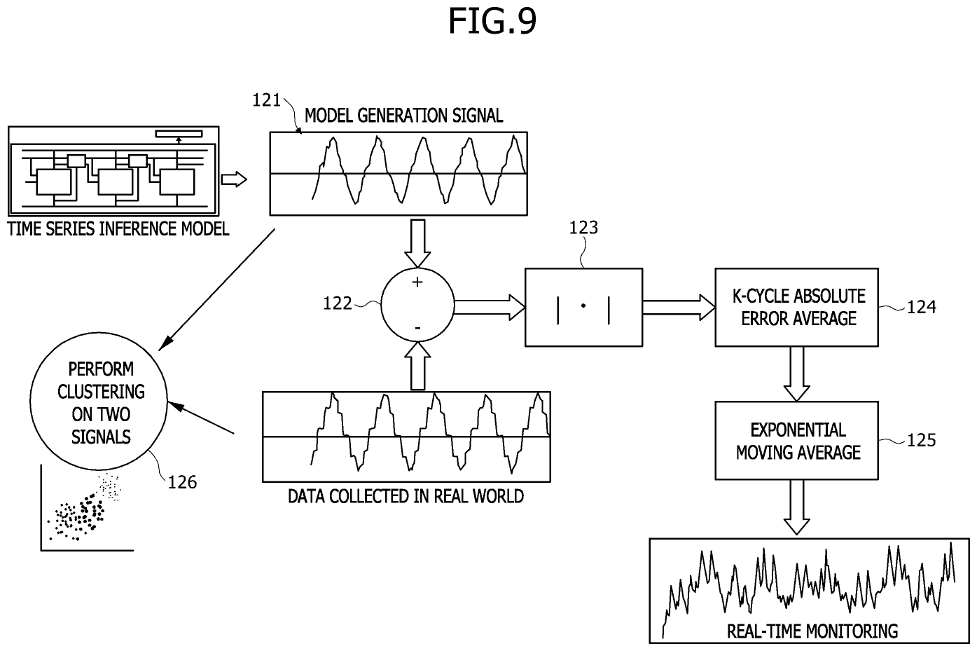

FIG. 9 is a configuration diagram of an error analysis model for a signal generated by a virtual sensor according to an embodiment of the present invention.

Referring to FIG. 9, two physical sensors #1 and #2 that are correlated with each other are installed in the real world, and data collected from the physical sensor #1 is input to a virtual sensor to predict a result of the physical sensor #2.

The signal error analysis module 73 obtains an absolute value 123 of an error 122 between a prediction result 121 of the virtual sensor and a measurement result 120 of the physical sensor to obtain an absolute error average 124 during a set period (K cycle). The error of the virtual sensor is monitored by performing an exponential moving average 125 on the K-cycle absolute error average 124. Further, clustering characteristics may be analyzed for the data collected in the real world and the data generated in the virtual sensor (126) so that a relationship between the two pieces of data can be analyzed.

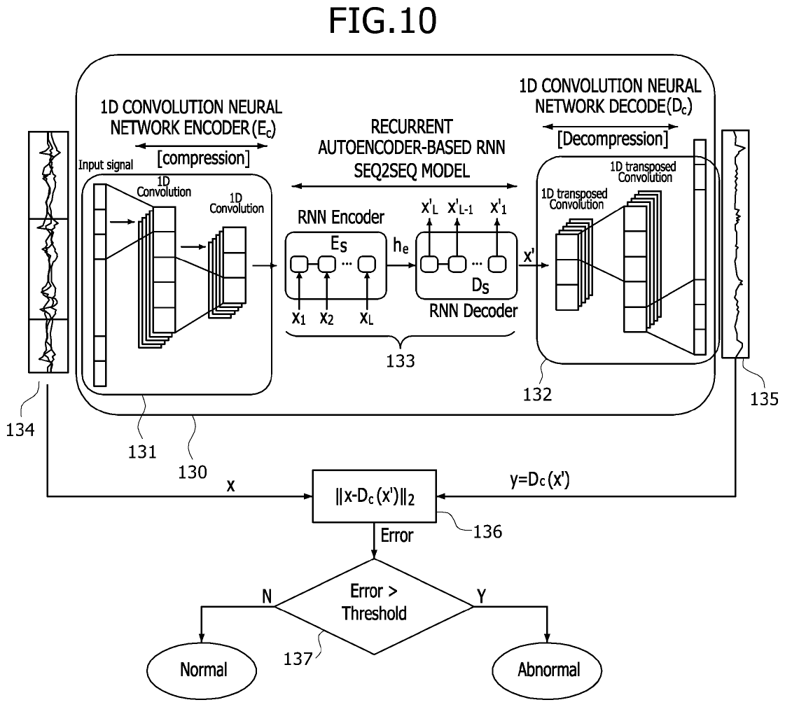

FIG. 10 is a diagram showing a deep learning model for detecting an abnormal signal in sensor data according to an embodiment of the present invention.

Referring to FIG. 10, a deep learning model 130 for detecting abnormal signals includes a 1D convolution neural network (CNN) encoder unit 131 that can extract and compress local features for input time series data, a 1D CNN decoder unit 132 for restoring time series data for compressed features reflecting time series characteristics, and an RNN autoencoder-based RNN unit 133 for generating data reflecting the trend characteristics of the time series input data.

The 1D CNN encoder unit 131 compresses and extracts local features inherent in input time series data 134, and has the effect of reducing the complexity of unsupervised learning of the RNN autoencoder.

The 1D CNN decoder unit 132 configures a 1D transpose CNN and performs a transpose convolution operation on the compression features of the 1D CNN encoder unit 131 to restore the time series data 135.

The RNN autoencoder-based RNN unit 133 generates the data reflecting the trend characteristics of time series input data. The RNN autoencoder-based RNN unit 133 measures an error between the time series data 134 measured by the physical sensors and the time series data 135 restored by the deep learning model 130 for detecting abnormal signals (136), and compares the measured error with a preset threshold (137). When the measured data is greater than the threshold, the data is an abnormal signal, and when the measured data is smaller than the threshold, the data is a normal signal.

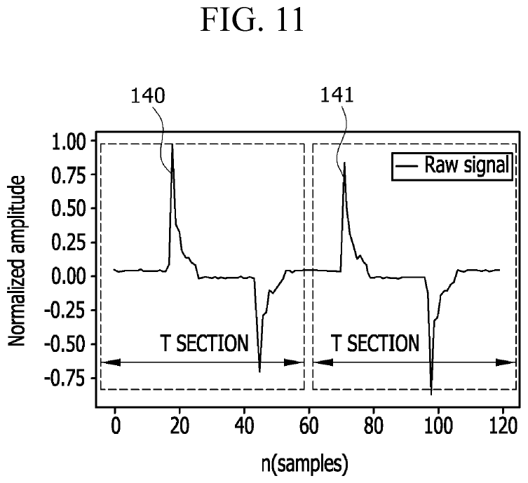

FIG. 11 is a diagram showing an example of detecting an abnormal signal in sensor data according to an embodiment of the present invention.

When a service is started by implementing virtual sensors on the basis of a plurality of pieces of physical sensor data that are correlated with each other, measurement data from the physical sensors replaced with virtual sensors is not provided as time has elapsed, and thus there are cases where it is difficult to determine whether the errors in predicted signals of the virtual sensors increase or whether there is an abnormality. That is, when the signal prediction performance of virtual sensors deteriorates, there is a need for retraining in order to additionally collect data at a current moment from physical sensors, which have been replaced with virtual sensors, and retrain to improve the performance of the deteriorated model.

Therefore, referring to FIG. 11, when an error between results predicted using a front T section 140 of the physical sensor data, which has a high correlation with the virtual sensor, as the encoder input sequence in FIG. 7 and a rear T section 141 of the same physical sensor data as the decoder input sequence in FIG. 7 and the measured result received from the corresponding physical sensor begins to increase significantly, there is a high probability that errors will also increase in an output value of the virtual sensor for other physical sensors that have a high correlation with the corresponding physical sensor. A time point (moment) at which the model for the virtual sensor is updated is determined using this method, data required for additional learning is collected, and the virtual sensor model is retrained.

The virtual sensor system for a digital twin application according to an aspect of the present invention can solve safety problems related to bridges by efficiently managing the safety of bridges, which cannot be managed systematically due to economic budget issues, using virtual sensors.

The virtual sensor system for a digital twin application according to another aspect of the present invention can increase reliability of social safety infrastructure by providing transparent data for bridges and reduce unnecessary social cost consumption by ensuring the safety of bridges.

The virtual sensor system for a digital twin application according to still another aspect of the present invention can significantly improve the reliability of a digital twin operated based on physical sensor data using values predicted by virtual sensors.

The components described in the example embodiments may be implemented by hardware components including, for example, at least one digital signal processor (DSP), a processor, a controller, an application-specific integrated circuit (ASIC), a programmable logic element, such as an FPGA, other electronic devices, or combinations thereof. At least some of the functions or the processes described in the example embodiments may be implemented by software, and the software may be recorded on a recording medium. The components, the functions, and the processes described in the example embodiments may be implemented by a combination of hardware and software.

The method according to example embodiments may be embodied as a program that is executable by a computer, and may be implemented as various recording media such as a magnetic storage medium, an optical reading medium, and a digital storage medium.

Various techniques described herein may be implemented as digital electronic circuitry, or as computer hardware, firmware, software, or combinations thereof. The techniques may be implemented as a computer program product, i.e., a computer program tangibly embodied in an information carrier, e.g., in a machine-readable storage device (for example, a computer-readable medium) or in a propagated signal for processing by, or to control an operation of a data processing apparatus, e.g., a programmable processor, a computer, or multiple computers. A computer program(s) may be written in any form of a programming language, including compiled or interpreted languages and may be deployed in any form including a stand-alone program or a module, a component, a subroutine, or other units suitable for use in a computing environment. A computer program may be deployed to be executed on one computer or on multiple computers at one site or distributed across multiple sites and interconnected by a communication network.

Processors suitable for execution of a computer program include, by way of example, both general and special purpose microprocessors, and any one or more processors of any kind of digital computer. Generally, a processor will receive instructions and data from a read-only memory or a random access memory or both. Elements of a computer may include at least one processor to execute instructions and one or more memory devices to store instructions and data. Generally, a computer will also include or be coupled to receive data from, transfer data to, or perform both on one or more mass storage devices to store data, e.g., magnetic, magneto-optical disks, or optical disks. Examples of information carriers suitable for embodying computer program instructions and data include semiconductor memory devices, for example, magnetic media such as a hard disk, a floppy disk, and a magnetic tape, optical media such as a compact disk read only memory (CD-ROM), a digital video disk (DVD), etc. and magneto-optical media such as a floptical disk, and a read only memory (ROM), a random access memory (RAM), a flash memory, an erasable programmable ROM (EPROM), and an electrically erasable programmable ROM (EEPROM) and any other known computer readable medium. A processor and a memory may be supplemented by, or integrated into, a special purpose logic circuit.

While the present invention has been described with reference to embodiments illustrated in the accompanying drawings, the embodiments should be considered in a descriptive sense only, and it should be understood by those skilled in the art that various alterations and other equivalent embodiments may be made. Therefore, the scope of the present invention should be defined by only the following claims.

What is claimed is:

1. A virtual sensor system for a digital twin application, comprising:
an edge gateway configured to collect data collected from physical sensors in the real world, apply the collected data to a virtual sensor model, and operate virtual sensors for configuring a digital twin world; and
a virtual sensor framework configured to train the virtual sensor model using data, which is measured by the physical sensors, from the edge gateway and distribute the virtual sensor model to the edge gateway.

2. The virtual sensor system of claim 1, wherein the virtual sensor model predicts time series data on the basis of correlation characteristics of the data collected from the physical sensors and the data collected from the physical sensors at a current moment in order to construct a digital twin world in the field of bridges.

3. The virtual sensor system of claim 1, wherein the virtual sensor model learns based on the data collected from the physical sensors that are correlated with each other and predicts time series data in an area where no physical sensor is installed.

4. The virtual sensor system of claim 1, wherein the edge gateway includes:
a database configured to collect the data from the physical sensors;
a data preprocessing module configured to preprocess the data stored in the database;
a virtual sensor database configured to store the virtual sensor model; and
a virtual sensor operation module configured to operate the virtual sensors through the virtual sensor model using the data preprocessed in the data preprocessing module.

5. The virtual sensor system of claim 4, wherein the edge gateway further includes an abnormal signal detection module configured to, when it is determined that the characteristics of the data preprocessed in the data preprocessing module have changed, request update of the virtual sensor model from the virtual sensor framework according to a distribution of the changed data.

6. The virtual sensor system of claim 5, wherein, when the data preprocessed in the data preprocessing module is an abnormal signal, the abnormal signal detection module transmits an alarm to an administrator so that the administrator is able to check whether there is an abnormality in the physical sensors.

7. The virtual sensor system of claim 6, wherein, when an error between time series data measured by the physical sensors and time series data restored by a deep learning model for detecting an abnormal signal is greater than a preset threshold, the abnormal signal detection module determines that the data is an abnormal signal, and when the error is smaller than the threshold, the abnormal signal detection module determines that the data is a normal signal.

8. The virtual sensor system of claim 1, wherein the virtual sensor framework includes:
a database configured to store preprocessed data from the edge gateway;
a virtual sensor learning model module configured to train the virtual sensor model with the data stored in the database and generate the virtual sensors;
a signal error analysis module configured to compare the data stored in the database with data of the virtual sensors input from the virtual sensor learning model module and correct errors of the virtual sensors; and
a data and error monitoring visualization engine configured to monitor the data stored in the database and the errors received from the signal error analysis module, determine whether the virtual sensor model needs to be updated, and request data collection for learning from the edge gateway according to a result of the determination.

9. The virtual sensor system of claim 8, wherein the virtual sensor learning model module includes an encoder configured to receive time series data of the physical sensors as an input and a decoder configured to receive the time series data of the physical sensors as an input, and
the virtual sensor learning model module sets the time series data of the physical sensors as an input of the encoder, sets the time series data of the physical sensors as an input of the decoder, sets a result of applying teacher forcing to an input sequence of the decoder as a target sequence of the decoder, and performs training of the virtual sensor model by inputting a last internal state of the encoder as an initial state of the decoder.

10. The virtual sensor system of claim 8, wherein the virtual sensor model includes a recurrent neural network (RNN)-based encoder and an RNN-based decoder,
the encoder and the decoder are composed of a cell RNN with a stacked structure, and
the cell RNN is implemented with at least one of a SimpleRNN, a long short-term memory (LSTM), and a gated recurrent unit (GRU).

11. The virtual sensor system of claim 10, wherein the virtual sensor model stores a final hidden state of the encoder in a state input representation layer (state), then inputs the final hidden state as the initial state of the decoder, generates a target sequence by shifting an input sequence of the decoder by one time step, and then sets an output signal that passes through a time-distributed fully connected layer as a target signal to perform learning, and
the time-distributed fully connected layer performs learning so that the decoder is able to know what a next target signal is at each time step.

12. The virtual sensor system of claim 10, wherein the signal error analysis module obtains an absolute value of an error between the data of the virtual sensors and data of the physical sensors, obtains an absolute error average during a set period, and then monitors the errors of the virtual sensors by performing an exponential moving average on the absolute error average.

13. A virtual sensor system for a digital twin application, comprising:
a database configured to collect data from physical sensors;
a data preprocessing module configured to preprocess the data stored in the database;
a virtual sensor database configured to store a virtual sensor model;
an abnormal signal detection module configured to, when it is determined that the characteristics of the data preprocessed in the data preprocessing module have changed, request update of the virtual sensor model from a virtual sensor framework according to a distribution of the changed data; and
a virtual sensor operation module configured to operate virtual sensors through the virtual sensor model using the data preprocessed in the data preprocessing module.

14. The virtual sensor system of claim 13, wherein, when an error between time series data measured by the physical sensors and time series data restored by a deep learning model for detecting an abnormal signal is greater than a preset threshold, the abnormal signal detection module determines that the data is an abnormal signal, and when the error is smaller than the threshold, the abnormal signal detection module determines that the data is a normal signal.

15. A virtual sensor system for a digital twin application, comprising:
a database configured to store preprocessed data from an edge gateway;
a virtual sensor learning model module configured to train a virtual sensor model with the data stored in the database and generate virtual sensors; and
a signal error analysis module configured to compare the data stored in the database with data of the virtual sensors input from the virtual sensor learning model module and correct errors of the virtual sensors.

16. The virtual sensor system of claim 15, further comprising a data and error monitoring visualization engine configured to monitor the data stored in the database and the errors received from the signal error analysis module, determine whether the virtual sensor model needs to be updated, and request data collection for learning from the edge gateway according to a result of the determination.

17. The virtual sensor system of claim 15, wherein the virtual sensor learning model module includes an encoder configured to receive time series data of the physical sensors as an input and a decoder configured to receive the time series data of the physical sensors as an input, and
the virtual sensor learning model module sets the time series data of the physical sensors as an input of the encoder, sets the time series data of the physical sensors as an input of the decoder, sets a result of applying teacher forcing to an input sequence of the decoder as a target sequence of the decoder, and performs training of the virtual sensor model by inputting a last internal state of the encoder as an initial state of the decoder.

18. The virtual sensor system of claim 17, wherein the virtual sensor model includes a recurrent neural network-based encoder and a recurrent neural network-based decoder,
the encoder and the decoder are composed of a cell recurrent neural network with a stacked structure,
the virtual sensor model stores a final hidden state of the encoder in a state input representation layer (state), then inputs the final hidden state as the initial state of the decoder, generates a target sequence by shifting an input sequence of the decoder by one time step, and then sets an output signal that passes through a time-distributed fully connected layer as a target signal to perform learning, and
the time-distributed fully connected layer performs learning so that the decoder is able to know what a next target signal is at each time step.

19. The virtual sensor system of claim 15, wherein the signal error analysis module obtains an absolute value of an error between the data of the virtual sensors and data of physical sensors, obtains an absolute error average during a set period, and then monitors errors of the virtual sensors by performing an exponential moving average on the absolute error average.
